(19) United States
(12) Patent Application Publication
(10) Pub. No.: US 2019/0207079 A1
(43) Pub. Date: Jul. 4, 2019

(54) Fabrication of Piezoelectric Composites Using High Temperature Dielectrophoresis Technique

(71) Applicant: Sabic Global Technologies, B.V., BERGEN OP ZOOM (NL)

(72) Inventors: Jibran KHALIQ, Schiedam (NL); Sybrand VAN DER ZWAAG, Schipluiden (NL); Wilhelm Albert GROEN, Eindhoven (NL); Theodorus Lambertus HOEKS, Bergen op Zoom (NL); Peter Hendrikus Theodorus VOLLENBERG, Eindhoven (NL)

(21) Appl. No.: 16/323,669

(22) PCT Filed: Jun. 27, 2017
(86) PCT No.: PCT/IB2017/053842

§ 371 Date: Feb. 6, 2019

Related U.S. Application Data
(60) Provisional application No. 62/371,948, filed on Aug. 8, 2016.

(51) Int. Cl. H01L 41/257; H01L 41/18; H01L 41/37; C08G 63/199; C08K 3/22

(52) U.S. Cl. CPC H01L 41/257; H01L 41/183; H01L 41/37; C08K 2003/2244; C08K 3/22; C08K 2201/001; C08G 63/199

(57) ABSTRACT

A method of making an aligned piezoelectric composite comprising contacting a thermoplastic material with a plurality of piezoelectric particles to form a thermoplastic material and piezoelectric particles mixture; applying an alternating current electric field across the thermoplastic material and piezoelectric particles mixture to structurally align the piezoelectric particles within the alternating current electric field; heating the thermoplastic material and piezoelectric particles mixture to form a molten polymer composite, while continuing to apply the alternating current electric field; maintaining the alternating current electric field across the molten polymer composite; cooling the molten polymer composite to form a structurally aligned piezoelectric composite, while continuing to apply the alternating current electric field; discontinuing the alternating current electric field; and applying a direct current electric field across the structurally aligned piezoelectric composite to align electric dipoles of the piezoelectric particles within the direct current electric field and to produce the aligned piezoelectric composite.

### CROSS REFERENCE TO RELATED APPLICATIONS

This application is a filing under 35 U.S.C. 371 of International Application No. PCT/IB2017/053842 filed Jun. 27, 2017, entitled, “Fabrication of Piezoelectric Composites Using High Temperature Dielectrophoresis Technique,” which claims the benefit of U.S. Provisional Application No. 62/371,948 filed Aug. 8, 2016, entitled “Fabrication of Piezoelectric Composites Using High Temperature Dielectrophoresis Technique,” which are incorporated by referenced herein in their entirety.

### TECHNICAL FIELD

The present disclosure relates to piezoelectric materials, more specifically piezoelectric composite materials and methods of making same.

### BACKGROUND

The use of piezoelectric materials has become more popular for a wide range of applications, including structural health monitoring, power harvesting, vibration sensing and actuation. However, piezoceramic materials are often prone to breakage and are difficult to apply to various shaped surfaces when in their monolithic form. One approach to alleviate these issues is to embed the fragile piezoceramics into a polymer matrix, thereby creating a piezoelectric polymer composite. The flexible nature of the polymer matrix protects the piezoelectric ceramic material from breaking under mechanical loading. Typically, the piezoelectric composites have randomly oriented filler particles. While there are various methods of aligning piezoelectric particles within a polymer matrix, such methods are generally time consuming and/or involve the use of solvents.

Thermosetting polymers can be being used to align piezoelectric particles inside the polymer matrix to achieve improved properties, for example by dicing the piezoelectric ceramic into columnar shapes and then filling them with a thermosetting polymer matrix. However, this method is cumbersome and time consuming, which adds complications and cost.

Another method of aligning piezoelectric particles within a polymer matrix is by using two component thermosetting polymers combined with dielectrophoresis to align the particles. In this method, only thermosetting polymers can be used, and they have to be two component polymers in order to initiate crosslinking during application of an electric field and to “freeze” the aligned filler particles.

Thermoplastic polymers typically use solvent based methods to align the particles inside the polymer matrix. The thermoplastic polymers can be dissolved in a solvent and then the particles can be aligned during the evaporation of the solvent, thereby capturing the particles alignments inside the matrix. However, this method requires a special setup to collect the evaporating solvent, which can be time consuming and costly. Thus, there is an ongoing need for the development of aligned piezoelectric composites and methods of making same.

### BRIEF SUMMARY

Disclosed herein is a method of making an aligned piezoelectric composite comprising (a) contacting a thermoplastic material with a plurality of piezoelectric particles to form a thermoplastic material and piezoelectric particles mixture; (b) applying an alternating current electric field across at least a portion of the thermoplastic material and piezoelectric particles mixture to structurally align at least a portion of the piezoelectric particles within the alternating current electric field; (c) heating at least a portion of the thermoplastic material and piezoelectric particles mixture to form a molten polymer composite, while continuing to apply the alternating current electric field; (d) maintaining the alternating current electric field across the molten polymer composite; (e) cooling at least a portion of the molten polymer composite to form a structurally aligned piezoelectric composite, while continuing to apply the alternating current electric field; (f) discontinuing the alternating current electric field; and (g) applying a direct current electric field across at least a portion of the structurally aligned piezoelectric composite to align at least a portion of electric dipoles of the piezoelectric particles within the direct current electric field and to produce the aligned piezoelectric composite.

Also disclosed herein is a method of making an aligned piezoelectric composite comprising (a) melting a mixture comprising a thermoplastic material and a plurality of piezoelectric particles to form a molten polymer composite; (b) structurally aligning the piezoelectric particles within the molten polymer composite via application of an alternating current electric field across at least a portion of the molten polymer composite to structurally align at least a portion of the piezoelectric particles within the alternating current electric field and to form a structured composite; and (c) poling the structured composite via application of a direct current electric field across at least a portion of the structured composite to align at least a portion of electric dipoles of the piezoelectric particles within the direct current electric field and to produce the aligned piezoelectric composite.

Further disclosed herein is a method of making an aligned piezoelectric composite comprising (a) contacting a thermoplastic material with a plurality of piezoelectric particles to form a thermoplastic material and piezoelectric particles mixture; (b) applying simultaneously an alternating current electric field and a direct current electric field across at least a portion of the thermoplastic material and piezoelectric particles mixture to structurally align at least a portion of the piezoelectric particles within the alternating current electric field and to align at least a portion of electric dipoles of the piezoelectric particles within the direct current electric field; (c) heating at least a portion of the thermoplastic material and piezoelectric particles mixture to form a molten polymer composite, while continuing to apply the alternating current electric field and the direct current electric field; (d) maintaining the alternating current electric field and the direct current electric field across the molten polymer composite; and (e) cooling at least a portion of the molten polymer composite to form the aligned piezoelectric composite, while continuing to apply the alternating current electric field and the direct current electric field.

Further disclosed herein is a method of making an aligned piezoelectric composite comprising (a) forming a molten polymer composite comprising a molten thermoplastic material with a plurality of piezoelectric particles dispersed therein; (b) applying simultaneously an alternating current electric field and a direct current electric field across at least a portion of the molten polymer composite to structurally align at least a portion of the piezoelectric particles within the alternating current electric field and to align at least a portion of electric dipoles of the piezoelectric particles within the direct current electric field; and (c) cooling at least a portion of the molten polymer composite to form the aligned piezoelectric composite, while continuing to apply the alternating current electric field and the direct current electric field.

Further disclosed herein is an aligned piezoelectric composite comprising a continuous polymeric phase having dispersed therein a plurality of piezoelectric particles, wherein the aligned piezoelectric composite is characterized by a top surface and a bottom surface, wherein the continuous polymeric phase comprises a thermoplastic polymer, wherein at least a portion of the plurality of piezoelectric particles have dipole moments that are aligned to within about 20 degrees of a direction perpendicular to the top surface and/or the bottom surface, wherein at least a portion of the plurality of piezoelectric particles are structurally aligned in piezoelectric chains, wherein at least a portion of the piezoelectric chains provide for connectivity between the top surface and the bottom surface of the aligned piezoelectric composite, and wherein a volumetric concentration of piezoelectric particles in the piezoelectric chains is at least about 5 times greater than an average volumetric concentration of piezoelectric particles in the aligned piezoelectric composite as a whole.

Further disclosed herein is an aligned piezoelectric composite comprising a continuous polymeric phase having dispersed therein a plurality of piezoelectric particles; wherein at least a portion of the plurality of piezoelectric particles are structurally aligned in piezoelectric chains; and wherein the aligned piezoelectric composite is characterized by a P₂ order parameter of equal to or greater than about 0.2, wherein the P₂ order parameter has by definition a value of 0 for 0-3 piezoelectric composites and a value of 1 for 1-3 piezoelectric composites.

Further disclosed herein is an aligned piezoelectric composite comprising a continuous polymeric phase having dispersed therein a plurality of piezoelectric particles; wherein the aligned piezoelectric composite comprises from about 0.1 vol. % to about 20 vol. % piezoelectric particles, based on the total volume of the aligned piezoelectric composite; wherein the aligned piezoelectric composite is characterized by a P₂ order parameter of equal to or greater than about 0.2, and wherein the P₂ order parameter has by definition a value of 0 for 0-3 piezoelectric composites and a value of 1 for 1-3 piezoelectric composites.

Further disclosed herein is a dielectrophoretically aligned piezoelectric composite comprising a continuous polymeric phase having dispersed therein a plurality of piezoelectric particles; wherein at least a portion of the plurality of piezoelectric particles are structurally aligned in piezoelectric chains; wherein the aligned piezoelectric composite is characterized by a P₂ order parameter of equal to or greater than about 0.2, wherein the P₂ order parameter has by definition a value of 0 for 0-3 piezoelectric composites and a value of 1 for 1-3 piezoelectric composites; wherein the aligned piezoelectric composite comprises from about 0.1 vol. % to about 20 vol. % piezoelectric particles, based on the total volume of the aligned piezoelectric composite; and wherein the piezoelectric chains are characterized by an average inter-particle distance of less than about 400 nm.

Further disclosed herein is a dielectrophoretically aligned piezoelectric composite comprising a continuous polymeric phase having dispersed therein a plurality of piezoelectric particles; wherein the dielectrophoretically aligned piezoelectric composite displays 1-3 piezoelectric composite behavior.

Further disclosed herein is a dielectrophoretically aligned piezoelectric composite comprising a continuous polymeric phase having dispersed therein a plurality of piezoelectric particles; wherein a first induced output charge per unit stress applied in a first direction is different by at least 25% when compared to a second induced output charge per unit stress applied in a second direction, and wherein the first direction is perpendicular to the second direction.

Further disclosed herein is an aligned piezoelectric composite comprising a continuous polymeric phase having dispersed therein a plurality of piezoelectric particles; wherein the aligned piezoelectric composite is characterized by an induced output charge that is non-uniform per unit stress applied in different directions.

Further disclosed herein is a piezoelectric composite displaying 1-3 piezoelectric behavior, wherein the piezoelectric composite is devoid of any piezoelectric columns or pillars extending continuously in the 1 direction of the composite from a first surface of the composite to a second surface of the composite, and wherein the first surface is spatially opposing the second surface.

### BRIEF DESCRIPTION OF THE DRAWINGS

For a detailed description of the preferred aspects of the disclosed methods, reference will now be made to the accompanying drawings in which:

FIG. 1 displays a schematic of an experimental mold setup for making an aligned piezoelectric composite;

FIGS. 2A-2B display a comparison of processing time for preparing an aligned piezoelectric composite between a thermoset polymer (2a) and a thermoplastic polymer (2b);

FIGS. 3a-3f display scanning electron micrographs of various piezoelectric composites;

FIGS. 4a-4d display graphs of the variation of the piezoelectric coefficient d₃₃ and piezoelectric voltage coefficient g₃₃ with the piezoelectric particle loading in aligned piezoelectric composites; and

FIGS. 5A-5B display a comparison of the variation of the piezoelectric coefficient d₃₃ and piezoelectric voltage coefficient g₃₃ for aligned piezoelectric composites and non-aligned piezoelectric composites.

### DETAILED DESCRIPTION

Disclosed herein are aligned piezoelectric composites and methods of making same. In an aspect, an aligned piezoelectric composite can comprise a continuous polymeric phase having dispersed therein a plurality of piezoelectric particles, wherein the aligned piezoelectric composite is characterized by a top surface and a bottom surface, wherein the continuous polymeric phase comprises a thermoplastic polymer, wherein at least a portion of the plurality of piezoelectric particles have dipole moments that are aligned to within about 20 degrees of a direction perpendicular to the top surface and/or the bottom surface, wherein at least a portion of the plurality of piezoelectric particles are structurally aligned in piezoelectric chains, wherein at least a portion of the piezoelectric chains provide for connectivity between the top surface and the bottom surface of the aligned piezoelectric composite, and wherein a volumetric concentration of piezoelectric particles in the piezoelectric chains is at least about 5 times greater than an average volumetric concentration of piezoelectric particles in the aligned piezoelectric composite as a whole.

In an aspect, a method of making an aligned piezoelectric composite can comprise (a) contacting a thermoplastic material with a plurality of piezoelectric particles to form a thermoplastic material and piezoelectric particles mixture; (b) applying an alternating current electric field across at least a portion of thermoplastic material and piezoelectric particles mixture to structurally align at least a portion of the piezoelectric particles within the alternating current electric field; (c) heating at least a portion of the thermoplastic material and piezoelectric particles mixture to form a molten polymer composite, while continuing to apply the alternating current electric field; (d) maintaining the alternating current electric field across the molten polymer composite; (e) cooling at least a portion of the molten polymer composite to form a structurally aligned piezoelectric composite, while continuing to apply the alternating current electric field; (f) discontinuing the alternating current electric field; and (g) applying a direct current electric field across at least a portion of the structurally aligned piezoelectric composite to align at least a portion of electric dipoles of the piezoelectric particles within the direct current electric field and to produce the aligned piezoelectric composite. The thermoplastic material can comprises a thermoplastic polymer and/or a thermoplastic oligomer. In such aspect, steps (b) and (c) can occur about concurrently.

Other than in the operating examples or where otherwise indicated, all numbers or expressions referring to quantities of ingredients, reaction conditions, and the like, used in the specification and claims are to be understood as modified in all instances by the term “about.” Various numerical ranges are disclosed herein. Because these ranges are continuous, they include every value between the minimum and maximum values. The endpoints of all ranges reciting the same characteristic or component are independently combinable and inclusive of the recited endpoint. Unless expressly indicated otherwise, the various numerical ranges specified in this application are approximations. The endpoints of all ranges directed to the same component or property are inclusive of the endpoint and independently combinable. The term “from more than 0 to an amount” means that the named component is present in some amount more than 0, and up to and including the higher named amount.

The terms “a,” “an,” and “the” do not denote a limitation of quantity, but rather denote the presence of at least one of the referenced item. As used herein the singular forms “a,” “an,” and “the” include plural referents.

As used herein, “combinations thereof” is inclusive of one or more of the recited elements, optionally together with a like element not recited, e.g., inclusive of a combination of one or more of the named components, optionally with one or more other components not specifically named that have essentially the same function. As used herein, the term “combination” is inclusive of blends, mixtures, alloys, reaction products, and the like.

Reference throughout the specification to “an aspect,” “another aspect,” “other aspect,” “some aspect,” and so forth, means that a particular element (e.g., feature, structure, property, and/or characteristic) described in connection with the aspect is included in at least an aspect described herein, and may or may not be present in other aspect. In addition, it is to be understood that the described element(s) can be combined in any suitable manner in the various aspect.

As used herein, the terms “inhibiting” or “reducing” or “preventing” or “avoiding” or any variation of these terms, include any measurable decrease or complete inhibition to achieve a desired result.

As used herein, the term “effective,” means adequate to accomplish a desired, expected, or intended result.

As used herein, the terms “comprising” (and any form of comprising, such as “comprise” and “comprises”), “having” (and any form of having, such as “have” and “has”), “including” (and any form of including, such as “include” and “includes”) or “containing” (and any form of containing, such as “contain” and “contains”) are inclusive or open-ended and do not exclude additional, unrecited elements or method steps.

Unless defined otherwise, technical and scientific terms used herein have the same meaning as is commonly understood by one of skill in the art.

Compounds are described herein using standard nomenclature. For example, any position not substituted by any indicated group is understood to have its valency filled by a bond as indicated, or a hydrogen atom. A dash (“—”) that is not between two letters or symbols is used to indicate a point of attachment for a substituent. For example, —CHO is attached through the carbon of the carbonyl group.

In an aspect, an aligned piezoelectric composite can be made by using any suitable methodology. A method of making an aligned piezoelectric composite can comprise a step of contacting a thermoplastic material with a plurality of piezoelectric particles to form a thermoplastic material and piezoelectric particles mixture.

The thermoplastic material can comprise a thermoplastic polymer, a thermoplastic oligomer, and the like, or combinations thereof. Generally, a thermoplastic material, or thermosoftening material, refers to a material that softens with heating (e.g., increasing temperature), and hardens with cooling (e.g., decreasing temperature). Thermoplastic materials can be exposed to repeated cycles of heating and cooling for molding or shaping into desired forms.

Generally, an oligomer has a molecular weight that is lower than a molecular weight of a polymer. For purposes of the disclosure herein, a thermoplastic oligomer can be characterized by a weight average molecular weight of less than the entanglement molecular weight. Generally, entanglement refers to the topological restriction of molecular motion by other polymeric or oligomeric chains. The thermoplastic oligomers can be referred to as pre-polymers, as the thermoplastic oligomers can be further polymerized to produce thermoplastic polymers. Further, for purposes of the disclosure herein, a thermoplastic polymer can be characterized by a weight average molecular weight of equal to or greater than the entanglement molecular weight.

Non-limiting examples of thermoplastic oligomers suitable for use as thermoplastic materials in the present disclosure include cyclic butylene terephthalate, polyarylene ether oligomers (e.g., polyphenylene ether oligomers), polyaryletherketone oligomers (e.g., polyether ether ketone oligomers), polyaryl sulfone oligomers, polyarylethersulfone oligomers, polycaprolactone oligomers, polyamide oligomers, nylon oligomers (e.g., PA6 oligomers, PA66 oligomers), polylactic acid oligomers, polycarbonate oligomers, and the like, or combinations thereof. As will be appreciated by one of skill in the art, and with the help of this disclosure, usually, the thermoplastic oligomers have a viscosity lower than a viscosity of the thermoplastic polymers, owing to a lower molecular weight, and as such could allow for easier movement of the piezoelectric particles during structurally aligning the particles, as will be described in more detail herein.

Non-limiting examples of thermoplastic polymers suitable for use as thermoplastic materials in the present disclosure include polybutylene terephthalate, cyclic polybutylene terephthalate, polyethylene terephthalate, polyethylene naphthalate, polylactic acid, polyaryletherketones (e.g., polyether ether ketone), polyvinylidene difluoride, polyglycolic acid, polycarbonate, polypropylene, polyarylene sulfides (e.g., polyphenylene sulfide), polyetherimide, polyetherimide sulfone, polyaryl sulfone, polyarylethersulfone, polyamides (e.g., aliphatic polyamides, aromatic polyamides) polycaprolactone, polyacrylates, polymethylmethacrylates, cellulose triacetate, and the like, derivatives thereof, copolymers thereof, or combinations thereof.

The piezoelectric particles can comprise any suitable piezoelectric material, for example lead zirconate titanate, sodium potassium niobate, lead magnesium niobate, barium titanate, quartz, aluminum orthophosphate, gallium orthophosphate, tourmaline, apatite, hydroxyapatite, lithium sulfate monohydrate, zinc oxide, lithium tantalite, polyvinylidene fluoride, lanthanum gallium silicate, potassium sodium tartrate, and the like, or combinations thereof. Piezoelectric materials (e.g., piezoelectric particles) are materials that produce an electric current when they are placed under mechanical stress. The piezoelectric particles can have any suitable shape, such as cylindrical, discoidal, rounded, oblong, spherical, tabular, ellipsoidal, equant, irregular, cubic, acicular, and the like, or combinations thereof.

The piezoelectric particles can be contacted with a thermoplastic material by using any suitable methodology. The piezoelectric particles and the thermoplastic material can be blended, mixed, ground up, crushed, milled, chopped, and the like, or combinations thereof, to form the thermoplastic material and piezoelectric particles mixture.

In an aspect, the thermoplastic material and piezoelectric particles mixture can be dried at a temperature of from about 50° C. to about 150° C., alternatively from about 75° C. to about 125° C., or alternatively from about 90° C. to about 110° C. The thermoplastic material and piezoelectric particles mixture can be dried for a time period of from about 30 minutes to about 48 hours, alternatively from about 4 hours to about 24 hours, or alternatively from about 10 hours to about 20 hours. In some aspects, drying the thermoplastic material and piezoelectric particles mixture can occur under vacuum. In other aspects, drying the thermoplastic material and piezoelectric particles mixture can occur at ambient pressure (e.g., without vacuum).

In some aspects, the thermoplastic material and piezoelectric particles mixture can be formed into a tablet under pressure. For example, tablets of the thermoplastic material and piezoelectric particles mixture can be formed in a tablet press by applying an appropriate amount of pressure (e.g., force in the form of pressure) to the thermoplastic material and piezoelectric particles mixture (e.g., in a manner similar to forming pharmaceutical tablets of various compositions).

The method of making an aligned piezoelectric composite can comprise a step of applying an alternating current (AC) electric field across at least a portion of thermoplastic material and piezoelectric particles mixture (e.g., dried thermoplastic material and piezoelectric particles mixture, tablet of thermoplastic material and piezoelectric particles mixture, etc.) to structurally align at least a portion of the piezoelectric particles within the AC electric field. In an aspect, the thermoplastic material and piezoelectric particles mixture can be placed between electrodes that generate the AC electric field, such that the thermoplastic material and piezoelectric particles mixture is in direct contact (e.g., electrical contact) with the electrodes. In another aspect, the thermoplastic material and piezoelectric particles mixture is not in direct contact with the electrodes that generate the AC electric field that is being applied to the thermoplastic material and piezoelectric particles mixture.

For purposes of the disclosure herein, the term “structurally aligning” refers to the movement of the piezoelectric particles within a polymer matrix, wherein the piezoelectric particles form piezoelectric chains that provide for electrical conductivity within the aligned piezoelectric composite. Further, for purposes of the disclosure herein, the terms “aligning,” “shaping” and “ orienting” can be used interchangeably and refer to the process of arranging the piezoelectric particles into piezoelectric chains. Further, for purposes of the disclosure herein, the terms “aligned,” “shaped” and “oriented” can be used interchangeably and refer to the piezoelectric composite comprising particles that have been arranged into piezoelectric chains. Further, for purposes of the disclosure herein, the terms “structurally aligning” and “electric field structuring” can be used interchangeably.

As will be appreciated by one of skill in the art, and with the help of this disclosure, “structurally aligning” as used herein refers to aligning piezoelectric particles via dielectrophoresis (DEP). Generally, DEP is a phenomenon in which a force is exerted on a dielectric particle (e.g., a piezoelectric particle) when it is subjected to a non-uniform electric field, such as an AC electric field, whereby the migration of dielectric particles occurs, e.g., the piezoelectric particles can form piezoelectric chains. Without wishing to be limited by theory, when a thermoplastic material and piezoelectric particles mixture is subjected to an AC electric field, the piezoelectric particles become polarized, can experience a mutual dipolar attraction, and can align themselves into chain-like structures (e.g., piezoelectric chains) that may be oriented parallel to the applied field. Further, without wishing to be limited by theory, when the piezoelectric chains form within a molten polymer, as will be described later herein, such piezoelectric chains can be “frozen” in their chain-like form by hardening the polymer, e.g., cooling the thermoplastic polymer.

The AC electric field can be characterized by a frequency of from about 1 Hz to about 5,000 Hz, alternatively from about 100 Hz to about 2,500 Hz, or alternatively from about 500 Hz to about 1,500 Hz. The AC electric field can be characterized by a field strength of from about 25 V/mm to about 10,000 V/mm, alternatively from about 100 V/mm to about 5,000 V/mm, or alternatively from about 1,000 V/mm to about 2,500 V/mm.

The method of making an aligned piezoelectric composite can comprise a step of heating at least a portion of the thermoplastic material and piezoelectric particles mixture to form a molten polymer composite, while continuing to apply the AC electric field. The thermoplastic material and piezoelectric particles mixture can be heated to a first temperature to form the molten polymer composite, wherein the first temperature is equal to or greater than a melting temperature of the thermoplastic material. In an aspect, the first temperature is a temperature effective to allow for movement of at least a portion of the piezoelectric particles within the thermoplastic material to structurally align the piezoelectric particles within the AC electric field. Without wishing to be limited by theory, the piezoelectric particles can migrate within the polymer matrix easier if the polymer matrix (e.g., thermoplastic material) is molten, as a viscosity of the polymer generally decreases with increasing the temperature. As will be appreciated by one of skill in the art, and with the help of this disclosure, thermoplastic polymers become soft with increasing temperature, thereby lowering their viscosity and allowing for alignment of the piezoelectric particles.

In some aspects, the first temperature can be equal to or greater than about 150° C., alternatively equal to or greater than about 200° C. , or alternatively equal to or greater than about 250° C.

In an aspect, the thermoplastic material and piezoelectric particles mixture can be heated by using any suitable heating source, such as an electrical heating source (e.g., a heater coil or band), microwave heating, gas fired heating, steam heating, furnace heating, and the like, or combinations thereof.

In some aspects, the molecular weight of the thermoplastic oligomers is lower than an entanglement molecular weight. In such aspects, and without wishing to be limited by theory, a viscosity of the oligomer is lower than a viscosity of the corresponding polymer, thereby allowing better movement of the piezoelectric particles to form piezoelectric chains. Heating the thermoplastic oligomer can result in further polymerization of the oligomer to form the corresponding thermoplastic polymer. For example, cyclic oligomers, such as cyclic butylene terephthalate, can ring open and polymerize, for example into cyclic polybutylene terephthalate. As another example, some thermoplastic oligomers can polymerize and form thermoplastic polymers in the presence of various polymerization initiators, such as free radical initiators, photo-initiators, cationic initiators, anionic initiators, and the like, or combinations thereof.

In some aspects, the step of applying an AC electric field across at least a portion of thermoplastic material and piezoelectric particles mixture can occur both prior to and about concurrently with the step of heating at least a portion of the thermoplastic material and piezoelectric particles mixture to form a molten polymer composite. As will be appreciated by one of skill in the art, and with the help of this disclosure, applying an AC electric field to the thermoplastic material and piezoelectric particles mixture prior to melting the thermoplastic material can allow for aligning of at least a portion of the piezoelectric particles into piezoelectric chains as soon as the thermoplastic material softens, e.g., prior to further polymerizing the thermoplastic material (e.g., thermoplastic oligomer) and/or prior to substantially completing any further polymerization of the thermoplastic material (e.g., thermoplastic oligomer).

In other aspects, the step of applying an AC electric field across at least a portion of thermoplastic material and piezoelectric particles mixture occurs about concurrently with the step of heating at least a portion of the thermoplastic material and piezoelectric particles mixture to form a molten polymer composite.

In yet other aspects, an AC electric field can be applied to the molten polymer composite subsequent to forming the molten polymer composite (as opposed to prior to forming the polymer composite and/or about concurrent with forming the polymer composite).

The method of making an aligned piezoelectric composite can comprise a step of maintaining the AC electric field across the molten polymer composite. In some aspects, the AC electric field can be maintained across the molten polymer composite for a time period of from about 1 second to about 10 minutes, alternatively from about 10 seconds to about 7.5 minutes, of alternatively from about 30 seconds to about 5 minutes. As will be appreciated by one of skill in the art, and with the help of this disclosure, maintaining the AC electric field across the molten polymer composite provides for forming piezoelectric chains and/or maintaining the already formed piezoelectric chains.

The method of making an aligned piezoelectric composite can comprise a step of cooling at least a portion of the molten polymer composite to form a structurally aligned piezoelectric composite, while continuing to apply the AC electric field. As will be appreciated by one of skill in the art, and with the help of this disclosure, maintaining the AC electric field during the cooling step provides for piezoelectric chains in the structurally aligned piezoelectric composite. Further, as will be appreciated by one of skill in the art, and with the help of this disclosure, if the AC electric field would be removed prior to the cooling step, at least a portion of the piezoelectric particles would migrate from their piezoelectric chains alignment, and as such the piezoelectric chains would not be present in the structurally aligned piezoelectric composite as desired.

Cooling at least a portion of the molten polymer composite can comprise allowing the polymer composite to reach a room temperature (e.g., ambient temperature).

In some aspects, cooling at least a portion of the molten polymer composite can further comprise removing a heating source used during heating the thermoplastic material and piezoelectric particles mixture. Cooling at least a portion of the molten polymer composite can further comprise quenching in a cooling fluid, such as cooling water, brine, oil, etc. In aspects where cooling of the molten polymer composite comprises quenching in a cooling fluid, the AC electric field is discontinued prior to quenching.

The method of making an aligned piezoelectric composite can comprise a step of applying a direct current (DC) electric field across at least a portion of the structurally aligned piezoelectric composite to align at least a portion of electric dipoles of the piezoelectric particles within the direct current electric field and to produce the aligned piezoelectric composite. Generally, a structurally aligned piezoelectric composite can comprise randomly oriented electric dipoles. As will be appreciated by one of skill in the art, and with the help of this disclosure, when a material such as a structurally aligned piezoelectric composite is subjected to a mechanical stress, each dipole rotates from its original orientation toward a direction that minimizes the overall electrical and mechanical energy stored in the dipole. Further, as will be appreciated by one of skill in the art, and with the help of this disclosure, if all the dipoles are initially randomly oriented (i.e., a net polarization of zero), their rotation may not significantly change the macroscopic net polarization of the material, and as such the piezoelectric effect exhibited will be negligible. The structurally aligned piezoelectric composite can be subjected to a DC electric field (e.g., can be poled) to provide for an initial state of the piezoelectric composite wherein at least a portion of the electric dipoles are oriented in the same direction. Without wishing to be limited by theory, during poling, the piezoelectric composite is subjected to a strong electric field (e.g., DC electric field) that orients the dipoles in the direction of the field.

In some aspects, the electrodes that generated the AC electric field can also be used for generating the DC electric field. In other aspects, the electrodes that generated the AC electric field can be removed and new electrodes can be applied (for example by metal sputtering) onto the structurally aligned piezoelectric composite.

The DC electric field can be characterized by a field strength of from about 50 V/mm to about 100,000 V/mm, alternatively from about 100 V/mm to about 75,000 V/mm, or alternatively from about 1,000 V/mm to about 50,000 V/mm. The DC electric field can be applied to the polymer composite for a time period of from about 1 minute to about 1 hour, alternatively from about 5 minutes to about 45 minutes, or alternatively from about 10 minutes to about 30 minutes.

In some aspects, the step of applying a DC electric field across the structurally aligned piezoelectric composite can occur at a second temperature, wherein the second temperature is less than a softening temperature of the thermoplastic material. As will be appreciated by one of skill in the art, and with the help of this disclosure, increasing the temperature while applying the DC electric field may facilitate the orientation of the dipoles. Further, as will be appreciated by one of skill in the art, and with the help of this disclosure, if the temperature would reach a softening temperature of the thermoplastic material, in the absence of an AC electric field, the structurally aligned piezoelectric chains could be disrupted.

In some aspects, a difference between the second temperature and the softening temperature of the thermoplastic material is equal to or greater than about 50° C., alternatively equal to or greater than about 75° C., or alternatively equal to or greater than about 100° C.

In an aspect, the second temperature can be equal to or greater than about 75° C., alternatively equal to or greater than about 100° C., or alternatively equal to or greater than about 125° C.

In some aspects, the aligned piezoelectric composite can be cooled to ambient temperature under the DC electric field. As will be appreciated by one of skill in the art, and with the help of this disclosure, maintaining the DC electric field during the cooling the aligned piezoelectric composite provides for maintaining a desired orientation of the dipoles in the aligned piezoelectric composite. Further, as will be appreciated by one of skill in the art, and with the help of this disclosure, if the DC electric field would be removed prior to the cooling the aligned piezoelectric composite, at least a portion of the dipoles could lose the desired orientation in the direction of the field. The DC electric field can be discontinued once the piezoelectric composite reaches the ambient temperature.

In some aspects, the method of making an aligned piezoelectric composite can comprise applying simultaneously an AC electric field and a DC electric field across at least a portion of the thermoplastic material and piezoelectric particles mixture to structurally align at least a portion of the piezoelectric particles within the AC electric field and to align at least a portion of electric dipoles of the piezoelectric particles within the direct current electric field. As will be appreciated by one of skill in the art, and with the help of this disclosure, applying simultaneously an AC electric field and a DC electric field can reduce the overall number of process steps, as well as the duration of the process. At least a portion of the thermoplastic material and piezoelectric particles mixture can be heated to form the molten polymer composite, while continuing to apply the AC electric field and the DC electric field. In an aspect, applying simultaneously an AC electric field and a DC electric field across at least a portion of the thermoplastic material and piezoelectric particles mixture and heating the thermoplastic material and piezoelectric particles mixture can occur about concurrently.

The AC electric field and the DC electric field can be maintained simultaneously across the molten polymer composite for a time period of from about 1 second to about 1 hour, alternatively from about 10 seconds to about 45 minutes, or alternatively from about 30 seconds to about 30 minutes.

The molten polymer composite can be cooled to form the aligned piezoelectric composite, while continuing to apply the AC electric field and the DC electric field.

In other aspects, the DC electric field can be applied simultaneously with the AC electric field only for a portion of the time period used for applying the AC electric field. For example, the DC electric field can be turned on and applied to the molten polymer composite subsequent to the AC electric field already being on and being applied to the molten polymer composite, and while maintaining the AC electric field across the molten polymer composite.

The aligned piezoelectric composite as described herein can comprise a continuous polymeric phase having dispersed therein a plurality of piezoelectric particles, wherein the continuous polymeric phase comprises a thermoplastic polymer. As will be appreciated by one of skill in the art, and with the help of this disclosure, when a thermoplastic oligomer is used for making the aligned piezoelectric composite, substantially all of the thermoplastic oligomer is converted to the thermoplastic polymer during the step of heating at least a portion of the thermoplastic material and piezoelectric particles mixture to form a molten polymer composite, and as such the aligned piezoelectric composite comprises thermoplastic polymer and substantially no thermoplastic oligomer. In some aspects, the aligned piezoelectric composite is substantially free of thermoplastic oligomer. For example, the aligned piezoelectric composite can comprise less than about 5 wt. %, less than about 4 wt. %, less than about 3 wt. %, less than about 2 wt. %, less than about 1 wt. %, less than about 0.5 wt. %, less than about 0.1 wt. %, or less than about 0.01 wt. % thermoplastic oligomer, based on the total weight of the aligned piezoelectric composite.

The aligned piezoelectric composite can comprise from about 0.1 vol. % to about 60 vol. %, alternatively from about 0.1 vol. % to about 20 vol. %, or alternatively from about 0.5 vol. % to about 10 vol. % piezoelectric particles, based on the total volume of the aligned piezoelectric composite.

In some aspects, at least 25 wt. %, alternatively at least 35 wt. %, or alternatively at least 50 wt. % of the piezoelectric particles are structurally aligned in piezoelectric chains in the aligned piezoelectric composite, based on the total weight of the piezoelectric particles.

The aligned piezoelectric composite can be characterized by a top surface and a bottom surface (e.g., a first surface and a second surface), wherein at least a portion of the plurality of piezoelectric particles have dipole moments that are aligned to within less than about 20 degrees, alternatively less than about 15 degrees, or alternatively less than about 10 degrees of a direction perpendicular to the top surface and/or the bottom surface, wherein at least a portion of the plurality of piezoelectric particles are structurally aligned in piezoelectric chains, wherein at least a portion of the piezoelectric chains provide for connectivity between the top surface and the bottom surface of the aligned piezoelectric composite. In some aspects, the top surface can be parallel to the bottom surface; e.g., the first surface can be parallel to the second surface. The top surface can be spatially opposing the bottom surface. The first surface can be spatially opposing the second surface.

The piezoelectric chains can have a higher density of piezoelectric particles as compared to spaces or volumes adjacent to the piezoelectric chains that do not contain piezoelectric chains. For example, a volumetric concentration of piezoelectric particles in the piezoelectric chains can be at least about 5 times greater, alternatively at least about 10 times greater, or alternatively at least about 20 times greater than an average volumetric concentration of piezoelectric particles in the aligned piezoelectric composite as a whole.

The piezoelectric chains can comprise from about 0.1 vol. % to about 60 vol. %, alternatively from about 1 vol. % to about 60 vol. %, alternatively from about 5 vol. % to about 60 vol. %, alternatively from about 10 vol. % to about 50 vol. %, or alternatively from about 20 vol. % to about 40 vol. % piezoelectric particles, and from about 40 vol. % to about 99.9 vol. %, alternatively from about 40 vol. % to about 99 vol. %, alternatively from about 40 vol. % to about 95 vol. %, alternatively from about 50 vol. % to about 90 vol. %, or alternatively from about 60 vol. % to about 80 vol. % thermoplastic polymer, based on the total volume of the piezoelectric chains.

The piezoelectric chains can be characterized by an aspect ratio of equal to or greater than about 2:1, alternatively equal to or greater than about 10:1, or alternatively equal to or greater than about 20:1. Generally, the aspect ratio of an object (e.g., piezoelectric chain) refers to a proportional relationship between its width and its height.

In an aspect, at least about 10%, alternatively at least about 25%, or alternatively at least about 50% of the piezoelectric chains are aligned to within less than about 10 degrees, alternatively less than about 5 degrees, or alternatively less than about 2.5 degrees of a direction perpendicular to the top surface and/or the bottom surface.

In some aspects, at least about 10%, alternatively at least about 25%, or alternatively at least about 50% of the piezoelectric chains are aligned to a direction perpendicular to the top surface and/or the bottom surface.

In some aspects, at least about 10%, alternatively at least about 25%, or alternatively at least about 50% of the piezoelectric chains are aligned to within less than about 10 degrees alternatively less than about 5 degrees, or alternatively less than about 2.5 degrees of each other.

In some aspects, a difference between a top surface piezoelectric particles concentration and a bottom surface piezoelectric particles concentration can be less than about 20%, alternatively less than about 15%, or alternatively less than about 10%. Without wishing to be limited by theory, the piezoelectric particles do not substantially settle under gravity or sediment during the process of making the aligned piezoelectric composite as disclosed herein, owing to the electric fields (e.g., AC electric field and/or DC electric field) applied.

In an aspect, the aligned piezoelectric composite can further comprise a top conductive layer deposited on at least a portion of the top surface and a bottom conductive layer deposited on at least a portion of the bottom surface. In some aspects, the top conductive layer and/or the bottom conductive layer can comprise at least a portion of the electrodes used for applying the AC electric field and/or the DC electric fields. The top conductive layer and/or the bottom conductive layer can comprise a conductive material. Non-limiting examples of conductive materials suitable for use in the present disclosure include a conductive metal (e.g., copper, aluminum, silver, gold, nickel, zinc, titanium, chromium, vanadium, tantalum, niobium, brass, iron, steel, stainless steel, metallic nanowires); conductive epoxy; graphene, graphite, carbon nanotubes; and the like; or combinations thereof.

The aligned piezoelectric composite disclosed herein can be characterized by a piezoelectric coefficient d₃₃ of equal to or greater than about 1 pC/N, alternatively equal to or greater than about 2 pC/N, or alternatively equal to or greater than about 3 pC/N. Generally, the piezoelectric coefficient d₃₃ refers to the polarization generated per unit of mechanical stress applied to a piezoelectric material (e.g., aligned piezoelectric composite) or, alternatively, refers the mechanical strain experienced by a piezoelectric material per unit of electric field applied. The first subscript to d (e.g., 3) usually indicates the direction of polarization generated in the material when the electric field is zero or, alternatively, is the direction of the applied field strength. The second subscript to d (e.g., 3) is the direction of the applied stress or the induced strain, respectively. As will be appreciated by one of skill in the art, and with the help of this disclosure, because the strain induced in a piezoelectric material by an applied electric field is the product of the value for the electric field and the value for d₃₃, d₃₃ is an important indicator of a material's suitability for strain-dependent (actuator) applications (the higher the value for d₃₃, the better).

In an aspect, the aligned piezoelectric composite can be characterized by a piezoelectric coefficient d₃₃ that is increased by equal to or greater than about 200%, alternatively equal to or greater than about 300%, or alternatively equal to or greater than about 400% when compared to a piezoelectric coefficient d₃₃ of an otherwise similar piezoelectric composite comprising piezoelectric particles that have not been structurally aligned into piezoelectric chains.

The aligned piezoelectric composite disclosed herein can be characterized by a piezoelectric voltage coefficient g₃₃ of equal to or greater than about 20 mV.m/N, alternatively equal to or greater than about 30 mV.m/N, or alternatively equal to or greater than about 40 mV.m/N. Generally, the piezoelectric voltage coefficient, g₃₃, refers to the electric field generated by a piezoelectric material (e.g., aligned piezoelectric composite) per unit of mechanical stress applied or, alternatively, is the mechanical strain experienced by a piezoelectric material per unit of electric displacement applied. The first subscript to g (e.g., 3) indicates the direction of the electric field generated in the material, or the direction of the applied electric displacement. The second subscript to g (e.g., 3) refers to the direction of the applied stress or the induced strain, respectively. As will be appreciated by one of skill in the art, and with the help of this disclosure, because the strength of the induced electric field produced by a piezoelectric material in response to an applied physical stress is the product of the value for the applied stress and the value for g₃₃, g₃₃ is important for assessing a material's suitability for sensing (sensor) applications (the higher the value for g₃₃, the better).

In an aspect, the aligned piezoelectric composite can be characterized by a piezoelectric voltage coefficient g₃₃ that is increased by equal to or greater than about 300%, alternatively equal to or greater than about 400%, or alternatively equal to or greater than about 500% when compared to a piezoelectric voltage coefficient g₃₃ of an otherwise similar piezoelectric composite comprising piezoelectric particles that have not been structurally aligned into piezoelectric chains.

The aligned piezoelectric composite disclosed herein can display 1-3 piezoelectric composite behavior. Generally, piezoelectric composites can be classified according to their connectivity (such as 1-3, 0-3, 2-2, etc.), wherein the first digit refers to the piezoelectric material, and wherein the second digit refers to the polymeric phase. For purposes of the disclosure herein, the term “connectivity” is defined as the number of dimensions through which the piezoelectric material is continuous. For example, 0-3 piezoelectric composites generally consist of piezoelectric particles in a polymeric matrix; wherein the piezoelectric particles do not provide for continuous connectivity in any direction, thereby rendering the first digit “0;” and wherein the polymeric matrix is continuous in all directions, thereby rendering the second digit “3.” As another example, conventional 1-3 piezoelectric composites generally consist of piezoelectric columns or pillars extending continuously in one direction of the composite (“1” direction of the composite), wherein the columns or pillars can be usually obtained by dicing larger chunks of piezoelectric material into continuous columns or pillars (as opposed to discrete pieces or particles of piezoelectric material that are in contact with each other, and in some aspects are forming piezoelectric chains). For purposes of the disclosure herein, the term “piezoelectric chain(s)” excludes continuous columns or pillars.

In an aspect, the aligned piezoelectric composite can be characterized by a P₂ order parameter of equal to or greater than about 0.2, alternatively equal to or greater than about 0.3, alternatively equal to or greater than about 0.4, alternatively equal to or greater than about 0.5, alternatively equal to or greater than about 0.6, alternatively equal to or greater than about 0.7, alternatively equal to or greater than about 0.8, alternatively from about 0.2 to about 1, alternatively from about 0.2 to about 0.9, alternatively from about 0.2 to about 0.8, alternatively from about 0.3 to about 0.75, or alternatively from about 0.4 to about 0.7, wherein the P₂ order parameter has by definition a value of 0 for 0-3 piezoelectric composites and a value of 1 for 1-3 piezoelectric composites. As will be appreciated by one of skill in the art, and with the help of this disclosure, the degree of geometric alignment of piezoelectric particles can be quantified by calculating an order parameter. A common order parameter is the P₂ order parameter, which can be used to quantify the average orientation of rod-like molecules, for instance, in liquid crystal phase analysis. For purposes of the disclosure herein, (i) the P₂ order parameter takes the value P₂ =0 for an isotropic phase, i.e., for a random sample, such as a 0-3 piezoelectric composite; and (ii) the P₂ order parameter takes the value P₂=1 for a fully aligned microstructure, such as a 1-3 piezoelectric composite.

In some aspects, the piezoelectric chains of the aligned piezoelectric composite can be characterized by an average inter-particle distance of less than about 500 nm, alternatively less than about 450 nm, alternatively less than about 400 nm, alternatively less than about 350 nm, alternatively less than about 300 nm, alternatively from about 100 nm to about 500 nm, alternatively from about 150 nm to about 450 nm, alternatively from about 200 nm to about 400 nm, or alternatively from about 250 nm to about 300 nm. In such aspects, the aligned piezoelectric composite comprises from about 0.1 vol. % to about 20 vol. % piezoelectric particles, based on the total volume of the aligned piezoelectric composite. The average inter-particle distance can be calculated back from the formula displayed in equation (1):

$${d}_{33} = \frac{{( 1 + R )}^{2} {ɛ}_{p} {φY}_{33 c} {d}_{33 c}}{( {ɛ}_{c} + R {ɛ}_{p} ) [ ( 1 + R φ ) {Y}_{33 c} + ( 1 - φ ) {RY}_{p} ]} \qquad ( 1 )$$

wherein d₃₃ is piezoelectric coefficient of the aligned piezoelectric composite; wherein R is the ratio of average particle size to average inter-particle distance; wherein ϑₚ and ε_{c} are the dielectric constants of the continuous polymeric phase and piezoelectric particles, respectively; wherein ϕ is the volume fraction of the piezoelectric particles; wherein Yₚ and Y_{33c}, are elastic moduli of the continuous polymeric phase and piezoelectric particles, respectively, in the direction of chain alignment; and wherein d₃₃c is the piezoelectric coefficient of the piezoelectric particles. The P₂ order parameter and the average inter-particle distance, and their use for characterizing piezoelectric composites are described in more detail in D. A. van den Ende et al., Journal of Applied Physics, 2010, vol. 107, 024107, which is incorporated by reference herein in its entirety.

In an aspect, the aligned piezoelectric composite can be characterized by an induced output charge that is non-uniform per unit stress applied in different directions. Generally, piezoelectric composites can transfer mechanical energy (e.g., stress) into electrical charge (e.g., electrical energy) that can be stored and/or used to power devices. As will be appreciated by one of skill in the art and with the help of this disclosure, stress can be applied to a piezoelectric composite in all directions. For example, an induced output charge that is generated in a direction parallel to the direction of the applied stress can be different than an induced output charge that is generated in a direction perpendicular to the direction of the applied stress. In some aspects, an induced output charge that is generated in a direction parallel to the direction of the applied stress (corresponding to a piezoelectric coefficient d₃₃) can be greater than an induced output charge that is generated in a direction perpendicular to the direction of the applied stress (corresponding to a piezoelectric coefficient d₃₁).

In some aspects, a first induced output charge per unit stress applied in a first direction can be different by at least 25%, alternatively at least 30%, alternatively at least 40%, alternatively at least 50%, or alternatively at least 75%, when compared to a second induced output charge per unit stress applied in a second direction. In such aspects, the first direction can be perpendicular to the second direction.

In an aspect, the aligned piezoelectric composite as described herein can be formed into any suitable article of manufacture by using any suitable methodology. Non-limiting examples of articles that can be made from the aligned piezoelectric composite of the present disclosure include a sensor, an actuator, a transducer, an ultrasound transducer, a pressure sensor, a piezoelectric speaker, a piezoelectric energy harvesting device, and combinations thereof.

In an aspect, a method of making an aligned piezoelectric composite can comprise (a) melting a mixture comprising a thermoplastic material and a plurality of piezoelectric particles to form a molten polymer composite; (b) structurally aligning the piezoelectric particles within the molten polymer composite via application of an alternating current electric field across at least a portion of the molten polymer composite to structurally align at least a portion of the piezoelectric particles within the alternating current electric field and to form a structured composite; and (c) poling the structured composite via application of a direct current electric field across at least a portion of the structured composite to align at least a portion of electric dipoles of the piezoelectric particles within the direct current electric field and to produce the aligned piezoelectric composite. In such aspect, the thermoplastic material can comprise cyclic butylene terephthalate, and the piezoelectric particles can comprise sodium potassium niobate.

In another aspect, a method of making an aligned piezoelectric composite can comprise (a) forming a molten polymer composite comprising a molten thermoplastic material with a plurality of piezoelectric particles dispersed therein; (b) applying simultaneously an alternating current electric field and a direct current electric field across at least a portion of the molten polymer composite to structurally align at least a portion of the piezoelectric particles within the alternating current electric field and to align at least a portion of electric dipoles of the piezoelectric particles within the direct current electric field; and (c) cooling at least a portion of the molten polymer composite to form the aligned piezoelectric composite, while continuing to apply the alternating current electric field and the direct current electric field.

In an aspect, an aligned piezoelectric composite can comprise a continuous polymeric phase having dispersed therein a plurality of piezoelectric particles, wherein the aligned piezoelectric composite is characterized by a top surface and a bottom surface, wherein the top surface is parallel to the bottom surface, wherein the continuous polymeric phase comprises a thermoplastic polymer, wherein at least a portion of the plurality of piezoelectric particles have dipole moments that are aligned to within about 10 degrees of a direction perpendicular to the top surface and the bottom surface, wherein at least a portion of the plurality of piezoelectric particles are structurally aligned in piezoelectric chains, wherein at least a portion of the piezoelectric chains provide for connectivity between the top surface and the bottom surface of the aligned piezoelectric composite, and wherein a volumetric concentration of piezoelectric particles in the piezoelectric chains is at least about 10 times greater than an average volumetric concentration of piezoelectric particles in the aligned piezoelectric composite as a whole.

In an aspect, the aligned piezoelectric composite, and methods of making same, as disclosed herein can advantageously display improvements in one or more composition characteristics when compared to an otherwise similar piezoelectric composite comprising piezoelectric particles that have not been structurally aligned into piezoelectric chains. As disclosed herein, the piezoelectric properties, such as piezoelectric coefficient d₃₃ and piezoelectric voltage coefficient g₃₃ are superior for the aligned piezoelectric composite when compared to an otherwise similar piezoelectric composite comprising piezoelectric particles that have not been structurally aligned into piezoelectric chains.

In an aspect, the method of making the aligned piezoelectric composite as disclosed herein can advantageously avoid the use of a solvent, thereby improving the efficiency of the method and reducing the overall manufacturing cost. Additional advantages of the aligned piezoelectric composite, and methods of making same, as disclosed herein can be apparent to one of skill in the art viewing this disclosure.

### EXAMPLES

The subject matter having been generally described, the following examples are given as particular embodiments of the disclosure and to demonstrate the practice and advantages thereof. It is understood that the examples are given by way of illustration and are not intended to limit the specification of the claims to follow in any manner.

### Example 1

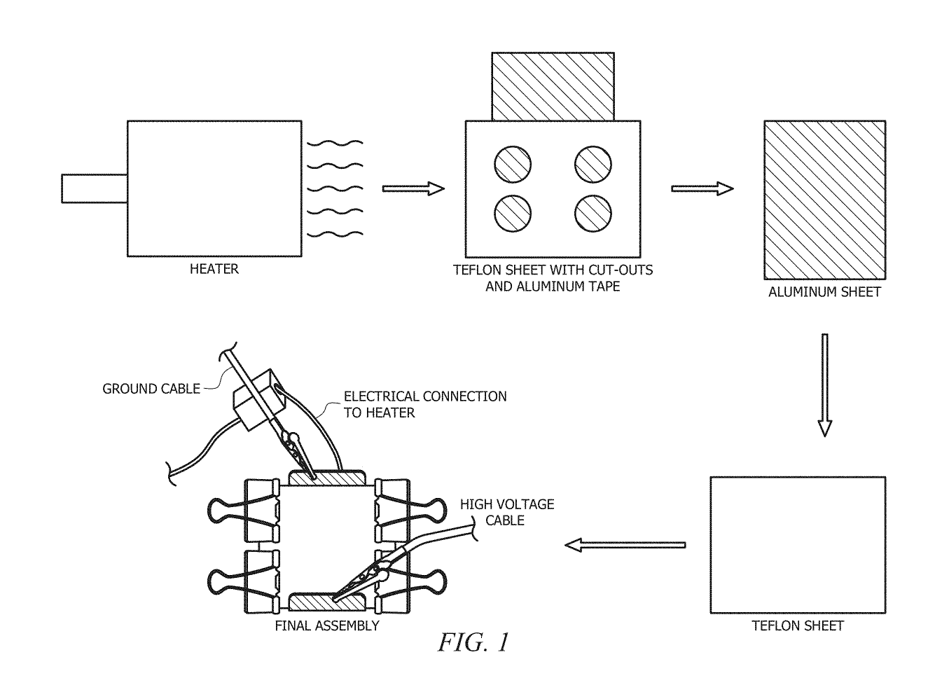

Aligned piezoelectric composites were prepared as follows. CBT 160 resin pellets, which is cyclic butylene terephthalate (CBT) resin with catalyst for use in composites available from Cyclics Corporation, were used. The CBT 160 resin pellets were ground to make a fine powder (CBT 160 resin powder) using a blender. PZ26 lead zirconate titanate (PZT), which is a high power and low loss material, was provided by Ferroperm Piezoceramics, Denmark. PZ26 lead zirconate titanate was processed as described in more detail in Hall D. A., Mori T., Comyn T. P., Ringgaard E., Wright J. P., Journal of Applied Physics 2013; 114:024103, which is incorporated by reference herein in its entirety. As will be appreciated by one of skill in the art, and with the help of this disclosure, PZT can be prepared by a variety of other methods, including but not limited to sol gel methods, molten salt synthesis, hydrothermal synthesis, etc. Sodium potassium niobate (KNN) lead free material was also used in the preparation of the composites. CBT 160 resin powder with different volume fractions of piezoelectric powder (i.e., 5, 10, 15 and 20% PZT or KNN) was mixed using zirconia balls. The mixed powders were dried overnight at 100° C. to remove any absorbed moisture. After drying the mixed powder, pellets of 15 mm diameter were made using a cold press under 5 ton force. A 1 mm TEFLON sheet was used as a mold and cut outs were made to house the pellets. Aluminum tape was used as the bottom electrode and it also served as a base for holding the liquid polymer. The middle section of the exposed adhesive of the tape was removed with acetone and then covered with an aluminum sheet to avoid the contact of adhesive with the polymer. After putting the pellets into the cut-outs, the mold was covered first an aluminum sheet (top electrode) and then alumina plate, and then clamped with paper clips to apply pressure. This whole assembly was put on top of a heater (Bach Resistor Ceramics GmbH) fitted with a temperature controller. Structurally aligning of the particles was carried out during melting of the polymer (at 235° C.) using dielectrophoresis (DEP) technique. An electric field of 2 KV/mm at a frequency of 1 KHz was applied using a function generator (Agilent) linked to a high voltage amplifier (Radiant Technologies). A heating rate of 400° C./min was used to melt the CBT 160 resin at 235° C. After melting, the mixture was held at this temperature for 3 minutes for the complete polymerization of CBT 160 resin to poly cyclic butylene terephthalate (pCBT). After three minutes, the heater was turned off and the mold was allowed to cool down under the electric field. At 160° C., the mold was quenched in water at room temperature to decrease the crystallinity of the composite. A schematic of the mold and the setup is displayed in the FIG. 1.

The composite discs were polished to remove the top and bottom layers and sputtered with gold electrodes on both sides of the composite samples using Quora Q300T D Dual Target Sequential Sputtering System. After sputtering, the composite samples were poled at 100° C. under a DC filed of 10 KV/mm in a water cooled oil bath (Julabo, SE Class III) for half an hour. The electric field was removed after cooling the samples down to room temperature.

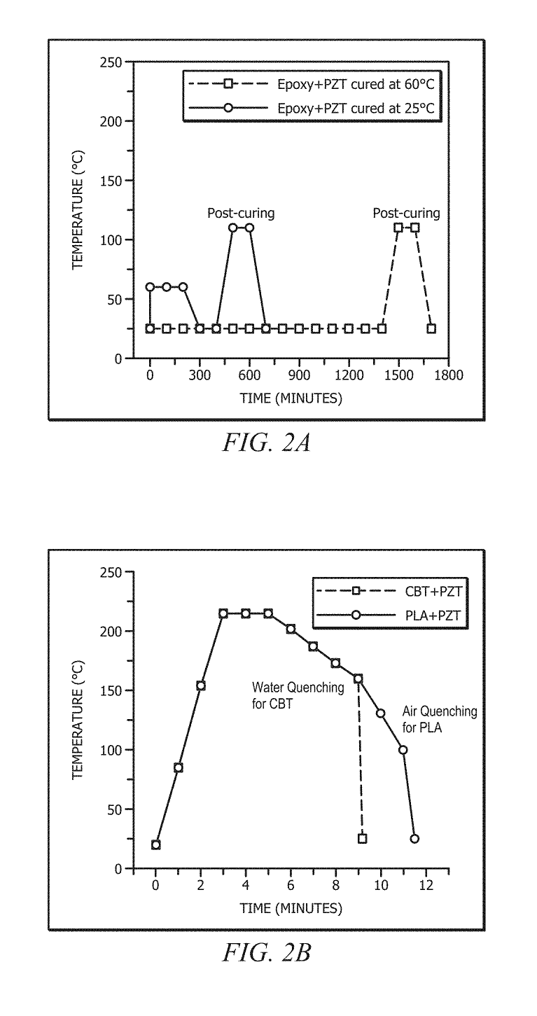

FIG. 2 displays a comparison of processing time for a thermoset polymer (FIG. 2a) versus a thermoplastic polymer (FIG. 2b). The composites prepared with thermoplastic polymers have a processing time much lower than the composites prepared with thermoset polymers. The samples were prepared by mixing PZT powder into CBT 160 resin and a hardener of a two component epoxy (diglycidyl ether of bisphenol-A (DGEBA) resin with a multifunctional aliphatic amine, poly (oxypropylene) diamine (POPD), curing agent). After mixing, the composite was cured either at 60° C. for 3 hours or at room temperature for 24 hours. After curing in both cases, the composite was post cured for an hour.

### Example 2

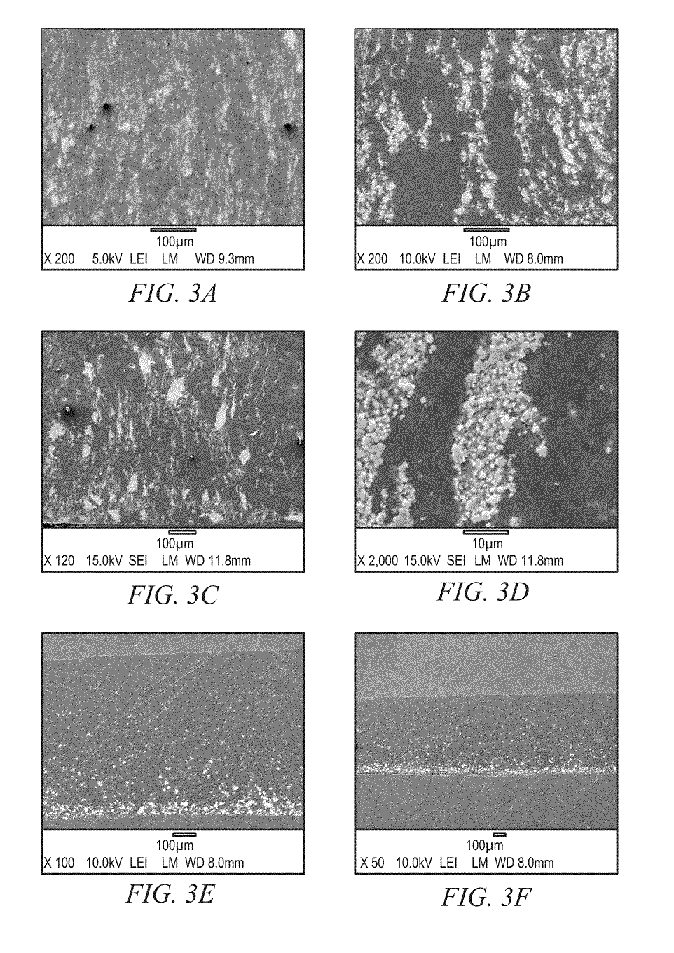

The aligned piezoelectric composites prepared as described in Example 1 were further analyzed. FIG. 3 shows the scanning electron micrograph (SEM) of the CBT-PZT composite recorded by using a JEOL JSM 7500F. The alignment of the particles can be clearly seen in the FIGS. 3a-3d. FIG. 3a displays a structured PZT-pCBT composite; FIG. 3b is a 200×magnification of the image in FIG. 3a; FIG. 3c displays a structured KNN-pCBT composite; and FIG. 3d is a 2000× magnification of the image in FIG. 3c. The degree of alignment was observed to depend upon the electric field which was applied. In unstructured composites, sedimentation can be clearly seen in FIGS. 3e-3f. FIG. 3e displays an unstructured PZT-pCBT composite; and FIG. 3f is a 50× magnification of the image in FIG. 3e. Sedimentation was not observed in the structured composites.

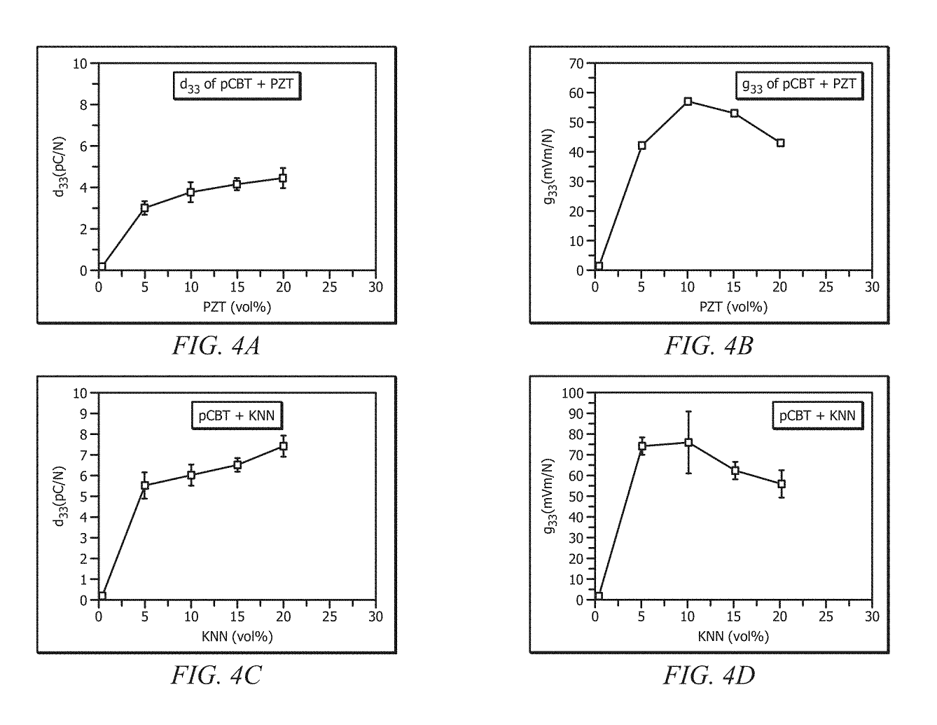

FIG. 4 shows the piezoelectric properties of the poled PZT-pCBT and KNN-pCBT composites. FIG. 4a displays d₃₃ values of pCBT as a function of PZT volume fraction; FIG. 4b displays g₃₃ values of pCBT as a function of PZT volume fraction; FIG. 4c displays d₃₃ values of pCBT as a function of KNN volume fraction; and FIG. 4d displays g₃₃ values of pCBT as a function of KNN volume fraction. The d₃₃ values, as well the g₃₃ values, increased with increasing the volume fraction of the piezoelectric material (PZT; KNN). For g₃₃, the maximum value was observed at about 10 vol. %, and the g₃₃ values decreased with further addition of piezoelectric powder into the pCBT.

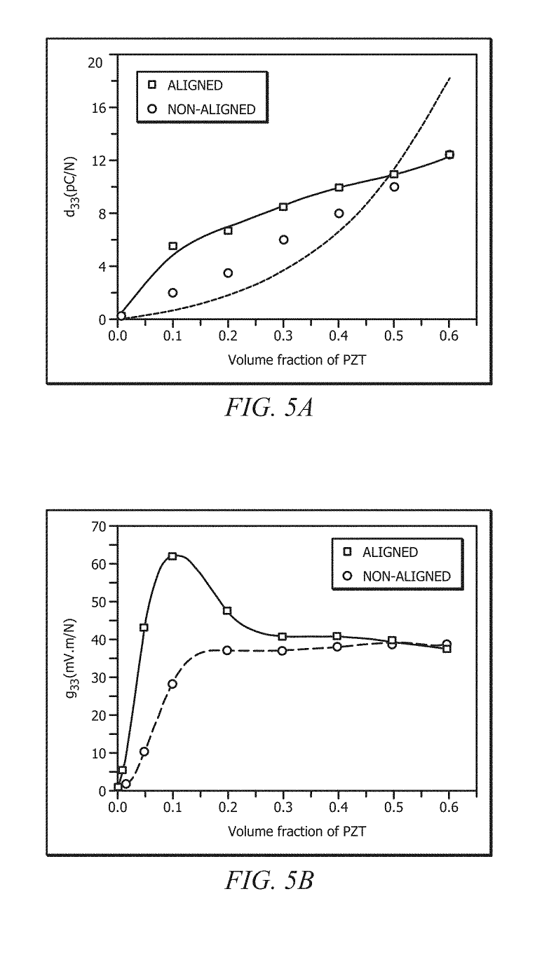

FIG. 5 displays a comparison of the variation of the piezoelectric coefficient d₃₃ and piezoelectric voltage coefficient g₃₃ for aligned piezoelectric composites (containing PZT) and non-aligned piezoelectric composites (containing PZT). The aligned piezoelectric composites display higher d₃₃ values and g₃₃ values when compared to non-aligned piezoelectric composites.

For the purpose of any U.S. national stage filing from this application, all publications and patents mentioned in this disclosure are incorporated herein by reference in their entireties, for the purpose of describing and disclosing the constructs and methodologies described in those publications, which might be used in connection with the methods of this disclosure. Any publications and patents discussed herein are provided solely for their disclosure prior to the filing date of the present application. Nothing herein is to be construed as an admission that the inventors are not entitled to antedate such disclosure by virtue of prior invention.

In any application before the United States Patent and Trademark Office, the Abstract of this application is provided for the purpose of satisfying the requirements of 37 C.F.R. § 1.72 and the purpose stated in 37 C.F.R. § 1.72(b) “to enable the United States Patent and Trademark Office and the public generally to determine quickly from a cursory inspection the nature and gist of the technical disclosure.” Therefore, the Abstract of this application is not intended to be used to construe the scope of the claims or to limit the scope of the subject matter that is disclosed herein. Moreover, any headings that can be employed herein are also not intended to be used to construe the scope of the claims or to limit the scope of the subject matter that is disclosed herein. Any use of the past tense to describe an example otherwise indicated as constructive or prophetic is not intended to reflect that the constructive or prophetic example has actually been carried out.

The present disclosure is further illustrated by the following examples, which are not to be construed in any way as imposing limitations upon the scope thereof. On the contrary, it is to be clearly understood that resort can be had to various other aspects, embodiments, modifications, and equivalents thereof which, after reading the description herein, can be suggest to one of ordinary skill in the art without departing from the spirit of the present invention or the scope of the appended claims.

### ADDITIONAL DISCLOSURE

A first aspect, which is a method of making an aligned piezoelectric composite comprising (a) contacting a thermoplastic material with a plurality of piezoelectric particles to form a thermoplastic material and piezoelectric particles mixture; (b) applying an alternating current electric field across at least a portion of the thermoplastic material and piezoelectric particles mixture to structurally align at least a portion of the piezoelectric particles within the alternating current electric field; (c) heating at least a portion of the thermoplastic material and piezoelectric particles mixture to form a molten polymer composite, while continuing to apply the alternating current electric field; (d) maintaining the alternating current electric field across the molten polymer composite; (e) cooling at least a portion of the molten polymer composite to form a structurally aligned piezoelectric composite, while continuing to apply the alternating current electric field; (f) discontinuing the alternating current electric field; and (g) applying a direct current electric field across at least a portion of the structurally aligned piezoelectric composite to align at least a portion of electric dipoles of the piezoelectric particles within the direct current electric field and to produce the aligned piezoelectric composite.

A second aspect, which is the method of the first aspect, wherein the thermoplastic material comprises a thermoplastic polymer, a thermoplastic oligomer, or combinations thereof.

A third aspect, which is the method of any one of the first and the second aspects, wherein steps (b) and (c) occur about concurrently.

A fourth aspect, which is the method of any one of the first through the third aspects, wherein the step (a) of contacting a thermoplastic material with a plurality of piezoelectric particles further comprises drying the thermoplastic material and piezoelectric particles mixture.

A fifth aspect, which is the method of any one of the first through the fourth aspects, wherein the alternating current electric field is characterized by a frequency of from about 1 Hz to about 5,000 Hz.

A sixth aspect, which is the method of any one of the first through the fifth aspects, wherein the alternating current electric field is characterized by a field strength of from about 25 V/mm to about 10,000 V/mm.

A seventh aspect, which is the method of any one of the first through the sixth aspects, wherein the thermoplastic material and piezoelectric particles mixture is heated to a first temperature to form the molten polymer composite, wherein the first temperature is equal to or greater than a melting temperature of the thermoplastic material.

An eighth aspect, which is the method of the seventh aspect, wherein the first temperature is a temperature effective to allow for movement of at least a portion of the piezoelectric particles within the thermoplastic material to structurally align the piezoelectric particles within the alternating current electric field.

A ninth aspect, which is the method of any one of the first through the eighth aspects, wherein the step (d) of maintaining the alternating current electric field across the molten polymer composite occurs for a time period of from about 1 second to about 10 minutes.

A tenth aspect, which is the method of any one of the first through the ninth aspects, wherein the step (e) of cooling at least a portion of the molten polymer composite further comprises (i) allowing the molten polymer composite to cool by removing a heating source used during steps (c) and (d); and/or (ii) quenching in a cooling fluid.

An eleventh aspect, which is the method of the tenth aspect, wherein the step (f) of discontinuing the alternating current electric field occurs prior to the step of quenching in a cooling fluid.

A twelfth aspect, which is the method of any one of the first through the eleventh aspects, wherein the direct current electric field is characterized by a field strength of from about 50 V/mm to about 100,000 V/mm.

A thirteenth aspect, which is the method of any one of the first through the twelfth aspects, wherein the step (g) of applying a direct current electric field occurs for a time period of from about 1 minute to about 1 hour.

A fourteenth aspect, which is the method of any one of the first through the thirteenth aspects, wherein the step (g) of applying a direct current electric field occurs at a second temperature, wherein the second temperature is less than a softening temperature of the thermoplastic material, and wherein a difference between the second temperature and the softening temperature of the thermoplastic material is equal to or greater than about 50° C.

A fifteenth aspect, which is the method of the fourteenth aspect, wherein the second temperature is equal to or greater than about 75 ° C.

A sixteenth aspect, which is the method of of any one of the first through the fifteenth aspects further comprising cooling the aligned piezoelectric composite to ambient temperature under the direct current electric field.

A seventeenth aspect, which is the method of the sixteenth aspect further comprising discontinuing the direct current electric field.

An eighteenth aspect, which is the method of the second aspect, wherein the thermoplastic oligomer comprises cyclic butylene terephthalate, polyarylene ether oligomers, polyphenylene ether oligomers, polyaryletherketone oligomers, polyether ether ketone oligomers, polyaryl sulfone oligomers, polyarylethersulfone polycaprolactone oligomers, polyamide oligomers, nylon oligomers, polylactic acid oligomers, polycarbonate oligomers, or combinations thereof.

A nineteenth aspect, which is a method of making an aligned piezoelectric composite comprising (a) melting a mixture comprising a thermoplastic material and a plurality of piezoelectric particles to form a molten polymer composite; (b) structurally aligning the piezoelectric particles within the molten polymer composite via application of an alternating current electric field across at least a portion of the molten polymer composite to structurally align at least a portion of the piezoelectric particles within the alternating current electric field and to form a structured composite; and (c) poling the structured composite via application of a direct current electric field across at least a portion of the structured composite to align at least a portion of electric dipoles of the piezoelectric particles within the direct current electric field and to produce the aligned piezoelectric composite.

A twentieth aspect, which is the method of the nineteenth aspect, wherein the step (b) of structurally aligning the piezoelectric particles within the molten polymer composite further comprises (i) cooling at least a portion of the molten polymer composite to form the structured composite, while continuing to apply the alternating current electric field; and (ii) discontinuing the alternating current electric field.

A twenty-first aspect, which is a method of making an aligned piezoelectric composite comprising (a) contacting a thermoplastic material with a plurality of piezoelectric particles to form a thermoplastic material and piezoelectric particles mixture; (b) applying simultaneously an alternating current electric field and a direct current electric field across at least a portion of the thermoplastic material and piezoelectric particles mixture to structurally align at least a portion of the piezoelectric particles within the alternating current electric field and to align at least a portion of electric dipoles of the piezoelectric particles within the direct current electric field; (c) heating at least a portion of the thermoplastic material and piezoelectric particles mixture to form a molten polymer composite, while continuing to apply the alternating current electric field and the direct current electric field; (d) maintaining the alternating current electric field and the direct current electric field across the molten polymer composite; and (e) cooling at least a portion of the molten polymer composite to form the aligned piezoelectric composite, while continuing to apply the alternating current electric field and the direct current electric field.

A twenty-second aspect, which is the method of the twenty-first aspect, wherein steps (b) and (c) occur about concurrently.

A twenty-third aspect, which is the method of any one of the twenty-first and the twenty-second aspects, wherein the step (d) of maintaining the alternating current electric field and the direct current electric field occurs for a time period of from about 1 second to about 1 hour.

A twenty-fourth aspect, which is a method of making an aligned piezoelectric composite comprising (a) forming a molten polymer composite comprising a molten thermoplastic material with a plurality of piezoelectric particles dispersed therein; (b) applying simultaneously an alternating current electric field and a direct current electric field across at least a portion of the molten polymer composite to structurally align at least a portion of the piezoelectric particles within the alternating current electric field and to align at least a portion of electric dipoles of the piezoelectric particles within the direct current electric field; and (c) cooling at least a portion of the molten polymer composite to form the aligned piezoelectric composite, while continuing to apply the alternating current electric field and the direct current electric field.

A twenty-fifth aspect, which is an aligned piezoelectric composite comprising a continuous polymeric phase having dispersed therein a plurality of piezoelectric particles, wherein the aligned piezoelectric composite is characterized by a top surface and a bottom surface, wherein the continuous polymeric phase comprises a thermoplastic polymer, wherein at least a portion of the plurality of piezoelectric particles have dipole moments that are aligned to within about 20 degrees of a direction perpendicular to the top surface and/or the bottom surface, wherein at least a portion of the plurality of piezoelectric particles are structurally aligned in piezoelectric chains, wherein at least a portion of the piezoelectric chains provide for connectivity between the top surface and the bottom surface of the aligned piezoelectric composite, and wherein a volumetric concentration of piezoelectric particles in the piezoelectric chains is at least about 5 times greater than an average volumetric concentration of piezoelectric particles in the aligned piezoelectric composite as a whole.

A twenty-sixth aspect, which is the aligned piezoelectric composite the twenty-fifth aspect, wherein the thermoplastic polymer comprises polybutylene terephthalate, cyclic polybutylene terephthalate, polyethylene terephthalate, polyethylene naphthalate, polylactic acid, polyaryletherketones, polyether ether ketone, polyvinylidene difluoride, polyglycolic acid, polycarbonate, polypropylene, polyarylene sulfides, polyphenylene sulfide, polyetherimide, polyetherimide sulfone, polyaryl sulfone, polyarylethersulfone, polyamides, aliphatic polyamides, aromatic polyamides, polycaprolactone, polyacrylates, polymethylmethacrylates, cellulose triacetate, derivatives thereof, copolymers thereof, or combinations thereof.

A twenty-seventh aspect, which is the aligned piezoelectric composite of any one of the twenty-fifth and the twenty-sixth aspects, wherein the piezoelectric particles comprise lead zirconate titanate, sodium potassium niobate, lead magnesium niobate, barium titanate, quartz, aluminum orthophosphate, gallium orthophosphate, tourmaline, apatite, hydroxyapatite, lithium sulfate monohydrate, zinc oxide, lithium tantalite, polyvinylidene fluoride, lanthanum gallium silicate, potassium sodium tartrate, or combinations thereof.

A twenty-eighth aspect, which is the aligned piezoelectric composite of any one of the twenty-fifth through the twenty-seventh aspects further comprising a top conductive layer deposited on at least a portion of the top surface and a bottom conductive layer deposited on at least a portion of the bottom surface.

A twenty-ninth aspect, which is the aligned piezoelectric composite of the twenty-eighth aspect, wherein the top conductive layer and/or the bottom conductive layer comprise a conductive material.

A thirtieth aspect, which is the aligned piezoelectric composite of the twenty-ninth aspect, wherein the conductive material comprises a conductive metal, copper, aluminum, silver, gold, nickel, zinc, titanium, chromium, vanadium, tantalum, niobium, brass, iron, steel, stainless steel, metallic nanowires; conductive epoxy; graphene, graphite, carbon nanotubes; or combinations thereof.

A thirty-first aspect, which is the aligned piezoelectric composite of any one of the twenty-fifth through the thirtieth aspects, wherein the top surface is parallel to the bottom surface.

A thirty-second aspect, which is the aligned piezoelectric composite of any one of the twenty-fifth through the thirty-first aspects, wherein the piezoelectric chains are characterized by an aspect ratio of equal to or greater than about 2:1.

A thirty-third aspect, which is the aligned piezoelectric composite of any one of the twenty-fifth through the thirty-second aspects, wherein at least about 10% of the piezoelectric chains are aligned to within about 10 degrees of a direction perpendicular to the top surface and/or the bottom surface.

A thirty-fourth aspect, which is the aligned piezoelectric composite of any one of the twenty-fifth through the thirty-third aspects, wherein at least about 10% of the piezoelectric chains are aligned to a direction perpendicular to the top surface and/or the bottom surface.

A thirty-fifth aspect, which is the aligned piezoelectric composite of any one of the twenty-fifth through the thirty-fourth aspects, wherein at least about 10% of the piezoelectric chains are aligned to within about 10 degrees of each other.

A thirty-sixth aspect, which is the aligned piezoelectric composite of any one of the twenty-fifth through the thirty-fifth aspects, wherein at least about 25 wt. % of the piezoelectric particles are structurally aligned in piezoelectric chains, based on the total weight of the piezoelectric particles.

A thirty-seventh aspect, which is the aligned piezoelectric composite of any one of the twenty-fifth through the thirty-sixth aspects comprising from about 0.1 vol. % to about 60 vol. % piezoelectric particles, based on the total volume of the aligned piezoelectric composite.

A thirty-eighth aspect, which is the aligned piezoelectric composite of any one of the twenty-fifth through the thirty-seventh aspects comprising from about 0.1 vol. % to about 20 vol. % piezoelectric particles, based on the total volume of the aligned piezoelectric composite.

A thirty-ninth aspect, which is the aligned piezoelectric composite of any one of the twenty-fifth through the thirty-eighth aspects, wherein the piezoelectric chains comprise from about 0.1 vol. % to about 60 vol. % piezoelectric particles, and from about 99.9 vol. % to about 40 vol. % thermoplastic polymer, based on the total volume of the piezoelectric chains.

A fortieth aspect, which is the aligned piezoelectric composite of any one of the twenty-fifth through the thirty-ninth aspects further characterized by a piezoelectric coefficient d₃₃ of equal to or greater than about 1 pC/N.

A forty-first aspect, which is the aligned piezoelectric composite of any one of the twenty-fifth through the fortieth aspects, wherein the aligned piezoelectric composite is characterized by a piezoelectric coefficient d₃₃ that is increased by equal to or greater than about 200% when compared to a piezoelectric coefficient d₃₃ of an otherwise similar piezoelectric composite comprising piezoelectric particles that have not been structurally aligned into piezoelectric chains.

A forty-second aspect, which is the aligned piezoelectric composite of any one of the twenty-fifth through the forty-first aspects further characterized by a piezoelectric voltage coefficient g₃₃ of equal to or greater than about 20 mV.m/N.

A forty-third aspect, which is the aligned piezoelectric composite of any one of the twenty-fifth through the forty-second aspects, wherein the aligned piezoelectric composite is characterized by a piezoelectric voltage coefficient g₃₃ that is increased by equal to or greater than about 300% when compared to a piezoelectric voltage coefficient g₃₃ of an otherwise similar piezoelectric composite comprising piezoelectric particles that have not been structurally aligned into piezoelectric chains.

A forty-fourth aspect, which is the aligned piezoelectric composite of any one of the twenty-fifth through the forty-third aspects, wherein a difference between a top surface piezoelectric particles concentration and a bottom surface piezoelectric particles concentration is less than about 20%.

A forty-fifth aspect, which is an article comprising the aligned piezoelectric composite of any one of the twenty-fifth through the forty-fourth aspects.

A forty-sixth aspect, which is the article of the forty-fifth aspect, wherein the article is selected from the group consisting of a sensor, an actuator, a transducer, an ultrasound transducer, a pressure sensor, a piezoelectric speaker, a piezoelectric energy harvesting device, and combinations thereof.

A forty-seventh aspect, which is an aligned piezoelectric composite comprising a continuous polymeric phase having dispersed therein a plurality of piezoelectric particles; wherein at least a portion of the plurality of piezoelectric particles are structurally aligned in piezoelectric chains; and wherein the aligned piezoelectric composite is characterized by a P₂ order parameter of equal to or greater than about 0.2, wherein the P₂ order parameter has by definition a value of 0 for 0-3 piezoelectric composites and a value of 1 for 1-3 piezoelectric composites.

A forty-eighth aspect, which is the aligned piezoelectric composite of the forty-seventh aspect, wherein the aligned piezoelectric composite comprises from about 0.1 vol. % to about 20 vol. % piezoelectric particles, based on the total volume of the aligned piezoelectric composite; and wherein the piezoelectric chains are characterized by an average inter-particle distance of less than about 400 nm.

A forty-ninth aspect, which is an aligned piezoelectric composite comprising a continuous polymeric phase having dispersed therein a plurality of piezoelectric particles; wherein the aligned piezoelectric composite comprises from about 0.1 vol. % to about 20 vol. % piezoelectric particles, based on the total volume of the aligned piezoelectric composite; wherein the aligned piezoelectric composite is characterized by a P₂ order parameter of equal to or greater than about 0.2, and wherein the P₂ order parameter has by definition a value of 0 for 0-3 piezoelectric composites and a value of 1 for 1-3 piezoelectric composites.

A fiftieth aspect, which is the aligned piezoelectric composite of the forty-ninth aspect, wherein at least a portion of the plurality of piezoelectric particles are structurally aligned in piezoelectric chains; wherein the piezoelectric chains are characterized by an average inter-particle distance of from about 100 nm to about 500 nm; and wherein the aligned piezoelectric composite is characterized by an induced output charge that is non-uniform per unit stress applied in different directions.

A fifty-first aspect, which is a dielectrophoretically aligned piezoelectric composite comprising a continuous polymeric phase having dispersed therein a plurality of piezoelectric particles; wherein at least a portion of the plurality of piezoelectric particles are structurally aligned in piezoelectric chains; wherein the aligned piezoelectric composite is characterized by a P₂ order parameter of equal to or greater than about 0.2, wherein the P₂ order parameter has by definition a value of 0 for 0-3 piezoelectric composites and a value of 1 for 1-3 piezoelectric composites; wherein the aligned piezoelectric composite comprises from about 0.1 vol. % to about 20 vol. % piezoelectric particles, based on the total volume of the aligned piezoelectric composite; and wherein the piezoelectric chains are characterized by an average inter-particle distance of less than about 400 nm.

A fifty-second aspect, which is the dielectrophoretically aligned piezoelectric composite of the fifty-first aspect, wherein a first induced output charge per unit stress applied in a first direction is different by at least 25% when compared to a second induced output charge per unit stress applied in a second direction, and wherein the first direction is perpendicular to the second direction.

A fifty-third aspect, which is a dielectrophoretically aligned piezoelectric composite comprising a continuous polymeric phase having dispersed therein a plurality of piezoelectric particles; wherein the dielectrophoretically aligned piezoelectric composite displays 1-3 piezoelectric composite behavior.

A fifty-fourth aspect, which is the dielectrophoretically aligned piezoelectric composite of the fifty-third aspect, wherein a first induced output charge per unit stress applied in a first direction is different by at least 25% when compared to a second induced output charge per unit stress applied in a second direction, and wherein the first direction is perpendicular to the second direction.

A fifty-fifth aspect, which is a dielectrophoretically aligned piezoelectric composite comprising a continuous polymeric phase having dispersed therein a plurality of piezoelectric particles; wherein a first induced output charge per unit stress applied in a first direction is different by at least 25% when compared to a second induced output charge per unit stress applied in a second direction, and wherein the first direction is perpendicular to the second direction.

A fifty-sixth aspect, which is an aligned piezoelectric composite comprising a continuous polymeric phase having dispersed therein a plurality of piezoelectric particles; wherein the aligned piezoelectric composite is characterized by an induced output charge that is non-uniform per unit stress applied in different directions.

A fifty-seventh aspect, which is the aligned piezoelectric composite of the fifty-sixth aspect displaying 1-3 piezoelectric composite behavior.

A fifty-eighth aspect, which is a piezoelectric composite displaying 1-3 piezoelectric behavior, wherein the piezoelectric composite is devoid of any piezoelectric columns or pillars extending continuously in the 1 direction of the composite from a first surface of the composite to a second surface of the composite, and wherein the first surface is spatially opposing the second surface.

A fifty-ninth aspect, which is the piezoelectric composite of the fifty-eighth aspect comprising a continuous polymeric phase having dispersed therein a plurality of piezoelectric particles.

A sixtieth aspect, which is the piezoelectric composite of the fifty-ninth aspect, wherein a first induced output charge per unit stress applied in a first direction is different by at least 25% when compared to a second induced output charge per unit stress applied in a second direction, and wherein the first direction is perpendicular to the second direction.

A sixty-first aspect, which is the piezoelectric composite of the sixtieth aspect, wherein the aligned piezoelectric composite is characterized by a P₂ order parameter of equal to or greater than about 0.2, wherein the P₂ order parameter has by definition a value of 0 for 0-3 piezoelectric composites and a value of 1 for 1-3 piezoelectric composites.

A sixty-second aspect, which is the piezoelectric composite of the sixty-first aspect, wherein at least a portion of the plurality of piezoelectric particles are structurally aligned in piezoelectric chains.

A sixty-third aspect, which is the piezoelectric composite of the sixty-second aspect, wherein the aligned piezoelectric composite comprises from about 0.1 vol. % to about 20 vol. % piezoelectric particles, based on the total volume of the aligned piezoelectric composite; and wherein the piezoelectric chains are characterized by an average inter-particle distance of less than about 400 nm.

A sixty-fourth aspect, which is the piezoelectric composite of the sixty-third aspect, wherein at least a portion of the plurality of piezoelectric particles have dipole moments that are aligned to within about 20 degrees of a direction perpendicular to the first surface and/or the second surface.

A sixty-fifth aspect, which is the piezoelectric composite of the sixty-fourth aspect, wherein a volumetric concentration of piezoelectric particles in the piezoelectric chains is at least about 5 times greater than an average volumetric concentration of piezoelectric particles in the piezoelectric composite as a whole.

A sixty-sixth aspect, which is the aligned piezoelectric composite of the twenty-fifth aspect displaying 1-3 piezoelectric behavior.

A sixty-seventh aspect, which is the aligned piezoelectric composite of any one of the twenty-fifth through the forty-fourth aspects, wherein the aligned piezoelectric composite is devoid of any piezoelectric columns or pillars extending continuously in the 1 direction of the composite between the top surface and the bottom surface of the aligned piezoelectric composite, wherein the top surface is spatially opposing the bottom surface.

A sixty-eighth aspect, which is the aligned piezoelectric composite of any one of the twenty-fifth through the forty-fourth aspects characterized by an induced output charge that is non-uniform per unit stress applied in different directions.

A sixty-ninth aspect, which is the aligned piezoelectric composite of any one of the twenty-fifth through the forty-fourth aspects, wherein a first induced output charge per unit stress applied in a first direction is different by at least 25% when compared to a second induced output charge per unit stress applied in a second direction, and wherein the first direction is perpendicular to the second direction.

A seventieth aspect, which is the aligned piezoelectric composite of any one of the twenty-fifth through the forty-fourth aspects, wherein the aligned piezoelectric composite is characterized by a P₂ order parameter of equal to or greater than about 0.2, wherein the P₂ order parameter has by definition a value of 0 for 0-3 piezoelectric composites and a value of 1 for 1-3 piezoelectric composites.

A seventy-first aspect, which is the aligned piezoelectric composite of any one of the twenty-fifth through the forty-fourth aspects, wherein the aligned piezoelectric composite comprises from about 0.1 vol. % to about 20 vol. % piezoelectric particles, based on the total volume of the aligned piezoelectric composite; and wherein the piezoelectric chains are characterized by an average inter-particle distance of less than about 500 nm.

While embodiments of the disclosure have been shown and described, modifications thereof can be made without departing from the spirit and teachings of the invention. The embodiments and examples described herein are exemplary only, and are not intended to be limiting. Many variations and modifications of the invention disclosed herein are possible and are within the scope of the invention.

Accordingly, the scope of protection is not limited by the description set out above but is only limited by the claims which follow, that scope including all equivalents of the subject matter of the claims. Each and every claim is incorporated into the specification as an embodiment of the present invention. Thus, the claims are a further description and are an addition to the detailed description of the present invention. The disclosures of all patents, patent applications, and publications cited herein are hereby incorporated by reference.

1-24. (canceled)

25. An aligned piezoelectric composite comprising a continuous polymeric phase having dispersed therein a plurality of piezoelectric particles, wherein the aligned piezoelectric composite is characterized by a top surface and a bottom surface, wherein the continuous polymeric phase comprises a thermoplastic polymer, wherein at least a portion of the plurality of piezoelectric particles have dipole moments that are aligned to within. about 20 degrees of a direction perpendicular to the top surface and/or the bottom surface, wherein at least a portion of the plurality of piezoelectric particles are structurally aligned in piezoelectric chains, wherein at least a portion of the piezoelectric chains provide for connectivity between the top surface and the bottom surface of the aligned piezoelectric composite, and wherein a volumetric concentration of piezoelectric particles in the piezoelectric chains is at least about 5 times greater than an average volumetric concentration of piezoelectric particles in the aligned piezoelectric composite as a whole.

26. The aligned piezoelectric composite of claim 25, wherein the thermoplastic polymer comprises polybutylene terephthalate, cyclic polybutylene terephthalate, polyethylene terephthalate, polyethylene naphthalate, polylactic acid, polyaryletherketones, polyether ether ketone, polyvinylidene difluoride polyglycolic acid, polycarbonate, polypropylene, polyarylene sulfides, polyphenylene sulfide, polyetherimide, polyetherimide sulfone, polyaryl sulfone, polyarylethersulfone, polyamides, aliphatic polyamides, aromatic polyamides, polycaprolactone, polyacrylates, polymethyhnethacrylates, cellulose triacetate, derivatives thereof, copolymers thereof, or combinations thereof.

27. The aligned piezoelectric composite of claim 25, wherein the piezoelectric particles comprise lead zirconate titanate, sodium potassium niobate, lead magnesium. niobate, barium titanate, quartz, aluminum orthophosphate, gallium orthophosphate, tourmaline, apatite, hydroxyapatite, lithium sulfate monohydrate, zinc oxide, lithium tantalite, polyvinylidene fluoride, lanthanum gallium silicate, potassium sodium tartrate, or combinations thereof.

28. The aligned piezoelectric composite of claim 25, further comprising a top conductive layer deposited on at least a portion of the top surface and a bottom conductive layer deposited on at least a portion of the bottom surface, wherein the top conductive layer and/or the bottom conductive layer comprise a conductive material, wherein the conductive material comprises a conductive metal, copper, aluminum, silver, gold, nickel, zinc, titanium, chromium, vanadium, tantalum, niobium, brass, iron, steel, stainless steel, metallic nanowires; conductive epoxy; graphene, graphite, carbon nanotubes; or combinations thereof.

29-30. (canceled)

31. The aligned piezoelectric composite of claim 25, wherein the top surface is parallel to the bottom surface and wherein the piezoelectric chains are characterized by an aspect ratio of equal to or greater than about 2:1.

32. (canceled)

33. The aligned piezoelectric composite of claim 25, wherein at least about 10% of the piezoelectric chains are aligned to within about 10 degrees of a direction perpendicular to the top surface and/or the bottom surface.

34. The aligned piezoelectric composite of claim 25, wherein at least about 10% of the piezoelectric chains are aligned to a direction perpendicular to the top surface and/or the bottom surface.

35. The aligned piezoelectric composite of claim 25, wherein at least about 10% of the piezoelectric chains are aligned to within about 10 degrees of each other.

36. The aligned piezoelectric composite of claim 25, wherein at least about 25 wt. % of the piezoelectric particles are structurally aligned in piezoelectric chains, based on the total weight of the piezoelectric particles.

37. (canceled)

38. The aligned piezoelectric composite of claim 25 comprising from about 0.1 vol. % to about 20 vol. % piezoelectric particles, based on the total volume of the aligned piezoelectric composite.

39. The aligned piezoelectric composite of claim 25, wherein the piezoelectric chains comprise from about 0.1 vol. % to about 60 vol. % piezoelectric particles, and from about 99.9 vol. % to about 40 vol. % thermoplastic polymer, based on the total volume of the piezoelectric chains.

40. The aligned piezoelectric composite of claim 25 further characterized by a piezoelectric coefficient d₃₃ of equal to or greater than about 1 pC/N and a piezoelectric voltage coefficient g₃₃ of equal to or greater than about 20 mV.m/N.

41. The aligned piezoelectric composite of claim 25, wherein the aligned piezoelectric composite is characterized by a piezoelectric coefficient d₃₃ that is increased by equal to or greater than about 200% when compared to a piezoelectric coefficient d₃₃ of an otherwise similar piezoelectric composite comprising piezoelectric particles that have not been structurally aligned into piezoelectric chains and wherein the aligned piezoelectric composite is characterized by a piezoelectric voltage coefficient g₃₃ that is increased by equal to or greater than about 300% when compared to a piezoelectric voltage coefficient g₃₃ of an otherwise similar piezoelectric composite comprising piezoelectric particles that have not been structurally aligned into piezoelectric chains.

42-43. (canceled)

44. The aligned piezoelectric composite of claim 25, wherein a difference between a top surface piezoelectric particles concentration and a bottom surface piezoelectric particles concentration is less than about 20%.

45-65. (canceled)

66. The aligned piezoelectric composite of claim 25 displaying 1-3 piezoelectric behavior.

67. The aligned piezoelectric composite of claim 25, wherein the aligned piezoelectric composite is devoid of any piezoelectric columns or pillars extending continuously in the 1 direction of the composite between the top surface and the bottom surface of the aligned piezoelectric composite, wherein the top surface is spatially opposing the bottom surface.

68. The aligned piezoelectric composite of claim 25 characterized by an induced output charge that is non-uniform per unit stress applied in different directions.

69. The aligned piezoelectric composite of claim 25, wherein a first induced output charge per unit stress applied in a first direction is different by at least 25% when compared to a second induced output charge per unit stress applied in a second direction, and wherein the first direction is perpendicular to the second direction.

70. The aligned piezoelectric composite of claim 25, wherein the aligned piezoelectric composite is characterized by a P₂ order parameter of equal to or greater than about 0.2, wherein the P₂ order parameter has by definition a value of 0 for 0-3 piezoelectric composites and a value of 1 for 1-3 piezoelectric composites.

71. The aligned piezoelectric composite of claim 25, wherein the aligned piezoelectric composite comprises from about 0.1 vol. % to about 20 vol. % piezoelectric particles, based on the total volume of the aligned piezoelectric composite; and wherein the piezoelectric chains are characterized by an average inter-particle distance of less than about 500 nm.
